(19) United States
(12) Patent Application Publication
(10) Pub. No.: US 2013/0342514 A1
(43) Pub. Date: Dec. 26, 2013

(54) DETECTION APPARATUS, DETECTION SYSTEM, AND DETECTION APPARATUS DRIVE METHOD

(71) Applicant: CANON KABUSHIKI KAISHA, Tokyo (JP)

(72) Inventors: Keigo Yokoyama, Honjo-shi (JP); Chiori Mochizuki, Sagamihara-shi (JP); Minoru Watanabe, Honjo-shi (JP); Masato Ofuji, Honjo-shi (JP); Jun Kawanabe, Kodama-gun (JP); Kentaro Fujiyoshi, Tokyo (JP); Hiroshi Wayama, Saitama-shi (JP)

(21) Appl. No.: 13/915,728

(22) Filed: Jun. 12, 2013

(30) Foreign Application Priority Data
Jun. 20, 2012 (JP) 2012-138929

(51) Int. Cl. G09G 5/00

(52) U.S. Cl. CPC G09G 5/003
USPC 345/204

(57) ABSTRACT

A detection apparatus includes a substrate which includes a plurality of pixels arranged in a matrix and adapted to generate pixel signals, a plurality of drive lines arranged in a column direction and each connected in common to a plurality of pixels in a row direction, a plurality of data lines arranged in the row direction and each connected in common to a plurality of pixels in the column direction, connection terminals smaller in number than the data lines, and a multiplexer unit provided between the connection terminals and the data lines; a read circuit provided with a reset switch for supplying a constant potential to the connection terminals and connected to the connection terminals; a drive circuit adapted to control driving of the plurality of pixels; and a control circuit adapted to supply a control signal to the substrate and the read circuit.

### BACKGROUND OF THE INVENTION

1. Field of the Invention

The present invention relates to a detection apparatus, detection system, and detection apparatus drive method which are applied to a medical diagnostic imaging system, nondestructive inspection apparatus, analysis apparatus using radiation, and the like.

2. Description of the Related Art

Recently, thin-film semiconductor manufacturing technology has been used for matrix substrates containing an array of pixels (pixel array) made up of a combination of switching devices such as TFTs (thin-film transistors) and conversion devices such as photoelectric conversion devices as well as for detection apparatus and radiation detection apparatus which use the matrix substrate. Recently, consideration has been given to building a multiplexer into the same substrate as that of the pixel array in such detection apparatus mainly for the purpose of reducing the number of connection terminals. U.S. Pat. No. 5,536,932 discloses a method for multiplexing plural data lines into a single data contact in a detection apparatus which includes a multiplexer made up of plural TFTs provided between the plural data lines and the data contact (connection terminal). However, with U.S. Pat. No. 5,536,932, KTC noise (noise caused by thermal fluctuations of electric charges) is generated when the TFTs used in the multiplexer are closed while they are caused to open and close for operation. On the other hand, when only pixels connected to some data lines are read preferentially instead of opening and closing the TFTs used in the multiplexer, part of signal charges accumulated in the pixels not connected electrically to the data contact is lost. U.S. Pat. No. 5,536,932 does not disclose any method for obtaining accumulated signal charges from all the pixels.

An object of the present invention is to provide a detection apparatus, detection system, and detection apparatus drive method which can reduce KTC noise generation while reducing the number of data contacts.

### SUMMARY OF THE INVENTION

A detection apparatus according to the present invention comprises a substrate which includes a plurality of pixels arranged in a matrix and adapted to generate pixel signals, a plurality of drive lines arranged in a column direction and each connected in common to a plurality of pixels in a row direction, a plurality of data lines arranged in the row direction and each connected in common to a plurality of pixels in the column direction, connection terminals smaller in number than the data lines, and a multiplexer unit provided between the connection terminals and the data lines; a read circuit provided with a reset switch for supplying a constant potential to the connection terminals and connected to the connection terminals; a drive circuit adapted to control driving of the plurality of pixels; and a control circuit adapted to supply a control signal to the substrate and the read circuit, wherein each of the plurality of pixels is provided with a conversion device for converting radiation or light into an electric charge and a switching device for transferring an electric signal based on the electric charge to the data line and adapted to generate a pixel signal based on the electric signal, the drive lines include a first drive line connected to control electrodes of the switching devices of some of the pixels in one row and a second drive line connected to control electrodes of the switching devices of others of the pixels in the one row, the data lines include a first data line connected to main electrodes of the switching devices of the pixels in one column and a second data line connected to main electrodes of the switching devices of the pixels in another column, the multiplexer unit includes a first switch adapted to connect the first data line to one of the connection terminals and a second switch adapted to connect the second data line to the one connection terminal, and the control circuit carries out a first step of turning on the first switch, and turning on and then turning off the reset switch, a second step of turning on and then turning off the switching devices of the pixels connected to the first drive line by the drive circuit, and then turning off the first switch, a third step of turning on the second switch, turning on and then turning off the reset switch, and turning on and then turning off the switching devices of the pixels connected to the second drive line by the drive circuit, and a fourth step of turning off the second switch, the first step, the second step, the third step, and the fourth step being carried out in this order. The installation of the multiplexer unit allows the number of connection terminals to be reduced. Also, the turn-on operation of the first switch or second switch enables reducing KTC noise generated by data line capacitance.

Further features of the present invention will become apparent from the following description of exemplary embodiments with reference to the attached drawings.

### BRIEF DESCRIPTION OF THE DRAWINGS

FIG. 1 is a conceptual diagram of a detection apparatus.

FIG. 2 is an equivalent circuit diagram for illustrating the detection apparatus.

FIGS. 3A and 3B are top views of the detection apparatus.

FIG. 4 is a sectional view of a pixel.

FIG. 5 is an equivalent circuit diagram for illustrating the detection apparatus.

FIG. 6 is a timing chart of the detection apparatus.

FIG. 7 is an equivalent circuit diagram for illustrating the detection apparatus.

FIG. 8 is a timing chart of the detection apparatus.

FIG. 9 is a conceptual diagram of the detection apparatus.

FIG. 10 is an equivalent circuit diagram for illustrating a detection apparatus.

FIG. 11 is a top view of the detection apparatus.

FIG. 12 is a timing chart of the detection apparatus.

FIG. 13 is a timing chart of the detection apparatus.

FIGS. 14A and 14B are diagrams showing imaginary output of the detection apparatus.

FIG. 15 is an equivalent circuit diagram for illustrating a detection apparatus.

FIG. 16 is a timing chart of the detection apparatus.

FIG. 17 is a conceptual diagram for illustrating a detection system.

### DESCRIPTION OF THE EMBODIMENTS

Preferred embodiments of the present invention will now be described in detail in accordance with the accompanying drawings.

### First Embodiment

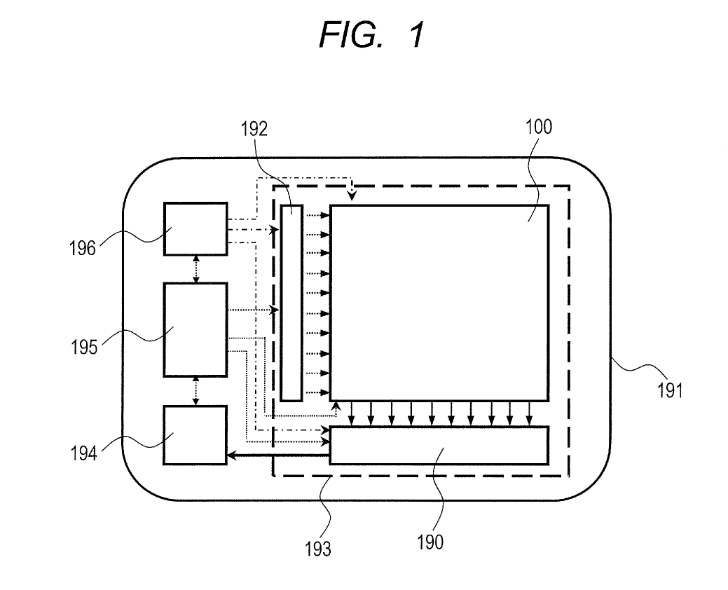

A configuration example of a detection apparatus 191 will be described with reference to FIG. 1. A detection unit 193 includes a supporting substrate 100, a drive circuit 192, and a read circuit 190. The supporting substrate 100 includes at least a pixel area 137 and a multiplexer unit 131. The drive circuit 192 is electrically connected with the pixel area 137 and adapted to control driving of plural pixels in the pixel area 137 by outputting an on-state voltage Vcom and an off-state voltage Voff. That is, the drive circuit 192 is designed to control a selected state and non-selected state of pixels 101. The read circuit 190 is electrically connected with the pixel area 137 and adapted to output electric signals from the pixel area 137 as image data. The detection apparatus 191 further includes a signal processing unit 194 adapted to process and output the image data received from the detection unit 193, a control circuit 195 adapted to supply respective control signals to various components and control operation of the detection unit 193, and a power supply circuit 196 adapted to supply respective biases to the various components.

The control circuit 195 receives a control signal from a control computer (not shown) and provides respective control signals to the supporting substrate 100, drive circuit 192, read circuit 190 and signal processing unit 194, where the supporting substrate 100 includes the pixel area 137. Also, the signal processing unit 194 receives electric-potential information about data lines 105 from the read circuit 190 during an irradiation period and transmits the electric-potential information to the control computer (not shown). The power supply circuit 196 includes a regulator and the like adapted to receive a voltage from an external power supply or built-in battery (not shown) and supply necessary voltages to the supporting substrate 100, drive circuit 192 and read circuit 190. The power supply circuit 196 is electrically connected with connection terminals 109. Incidentally, although the drive circuit 192, read circuit 190, signal processing unit 194, control circuit 195 and power supply circuit 196 are each represented by a single block, this does not mean that each of them is made up of one integrated circuit. Each of them may be made up of plural integrated circuits or all of them may be provided in a single integrated circuit. Besides, the above description is also applicable to other embodiments of the present invention as appropriate.

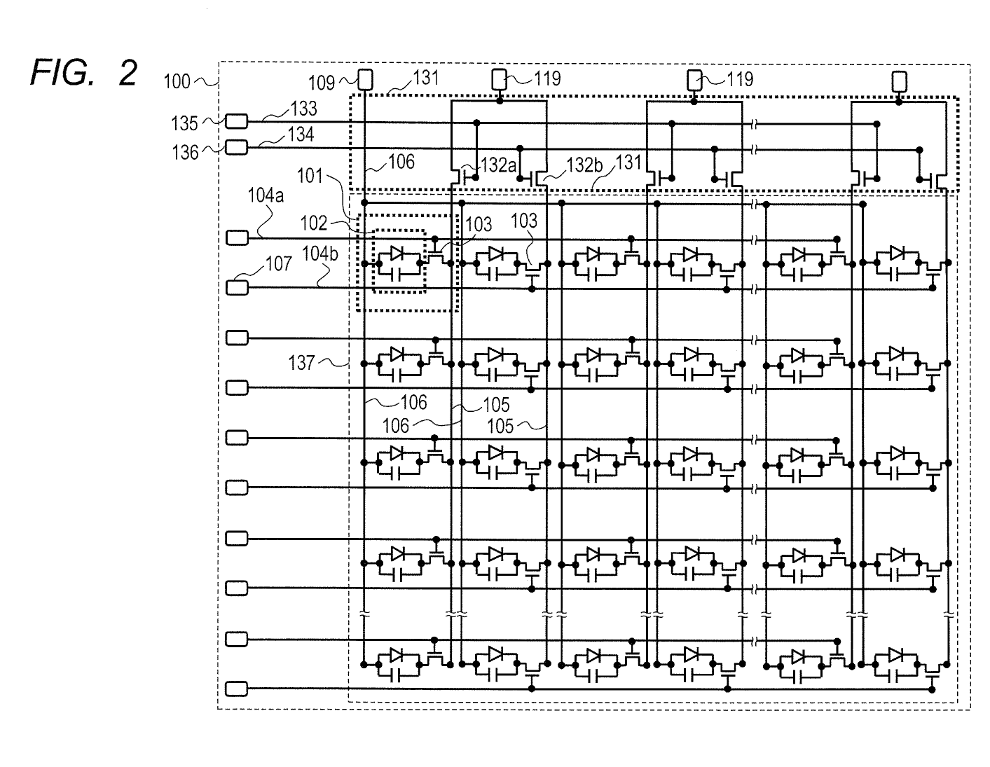

FIG. 2 is a diagram showing a configuration example of the detection apparatus according to a first embodiment of the present invention. The detection apparatus includes the pixel area 137 containing plural pixels 101 arranged in a matrix on the supporting substrate 100. The pixels 101 are intended to generate pixel signals (electric signals) according to radiation or light. Each of the plural pixels 101 includes a conversion device 102 adapted to convert radiation or light into an electric charge and a first switching device 103 adapted to transfer an electric signal to the data line 105 based on the electric charge resulting from the conversion by the conversion device 102. As the conversion devices 102, the present embodiment includes a scintillator adapted to convert radiation into light and a photoelectric conversion device adapted to convert the light into an electric charge, but the present embodiment is not limited to this. A direct conversion device adapted to convert radiation directly into an electric charge may be used as the conversion device 102. Also, as the switching device 103 an amorphous silicon or polycrystalline silicon thin-film transistor (TFT) may be used. Although silicon is used here as a semiconductor material, the present embodiment is not limited to this and another semiconductor material such as germanium may be used. More desirably, a polycrystalline silicon TFT is used as the switching device 103. A first electrode of the conversion device 102 is electrically connected with a first main electrode of the switching device 103 and a second electrode of the conversion device 102 is electrically connected with a bias line 106. The bias line 106 is connected in common to the second electrodes of the plural conversion devices 102 and electrically connected to the external power supply circuit 196 shown in FIG. 1 via the connection terminal 109.

A second main electrode of the switching device 103 is electrically connected with the data line 105. The data line 105 is connected in common to the second main electrodes of the plural switching devices 103 arranged in a column direction as well as to first main electrodes of switches 132a and 132b in the multiplexer unit 131. Second main electrodes of the switches 132a and 132b are connected to the second main electrode of one of adjacent switches 132a and 132b as well as to a connection terminal 119. The connection terminal 119 is electrically connected to the external read circuit 190 shown in FIG. 1. Control electrodes of the switches 132a and 132b are electrically connected with a drive line 133 or a drive line 134. The control electrodes of the two switches 132a and 132b connected to the same connection terminal 119 are connected with different drive lines 133 and 134, respectively. The plural data lines 105 are arranged in the row direction and are each connected in common to plural pixels 101 in the column direction. The data lines 105 include a first data line connected to the main electrodes of the switching devices 103 of the pixels 101 in one column (the pixels in the first column) and a second data line connected to the main electrodes of the switching devices 103 of the pixels 101 in another column (the pixels in the second column). The connection terminals 119, which are connected to the read circuit 190 shown in FIG. 1, are smaller in number than the data lines 105. The multiplexer unit 131 is provided between the connection terminals 119 and the data lines 105 and provided with the first switch 132a adapted to connect the first data line 105 to one of the connection terminals 119. Furthermore, the multiplexer unit 131 is provided with the second switch 132b adapted to connect the second data line 105 to one of the connection terminals 119.

The drive lines 133 and 134 are connected to connection terminals 135 and 136, respectively, and supplied with control signals from the external control circuit 195 shown in FIG. 1. Control electrodes of the plural switching devices 103 in the pixels 101 arranged in one row are electrically connected with one of two drive lines 104a and 104b. Out of the switching devices 103 which can be made electrically continuous with one connection terminal 119 via two switches 132a and 132b, two switching devices 103 adjacent to a same row are connected to different drive lines 104a and 104b, respectively. Plural drive lines 104a and 104b are arranged in the column direction and are each connected in common to plural pixels 101 in the row direction. The first drive line 104a is connected to control electrodes of the switching devices 103 of some of the pixels 101 (pixels 101 in odd-numbered columns) in one row. The second drive line 104b is connected to control electrodes of the switching devices 103 of others of the pixels 101 (pixels 101 in even-numbered columns) in the one row. The drive lines 104a and 104b are connected to a connection terminal 107 and supplied with control signals from the external drive circuit 192. Also, the connection terminals 109, 119, 135 and 136 are placed between an edge of the supporting substrate 100 and the pixel area 137.

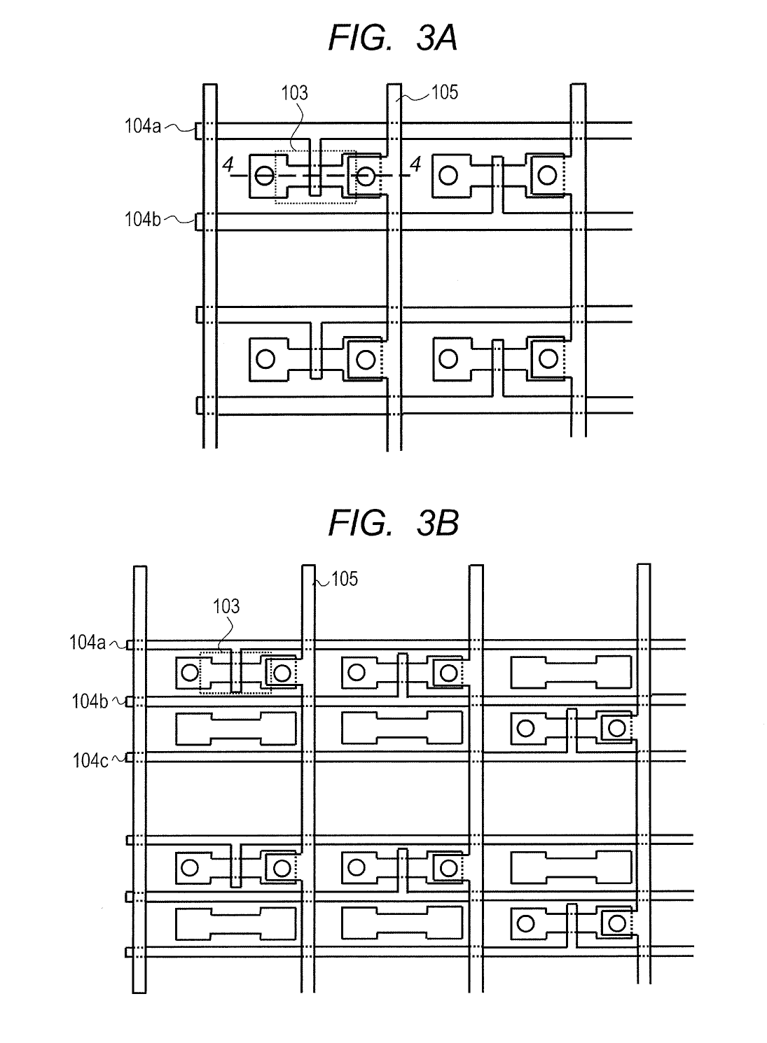

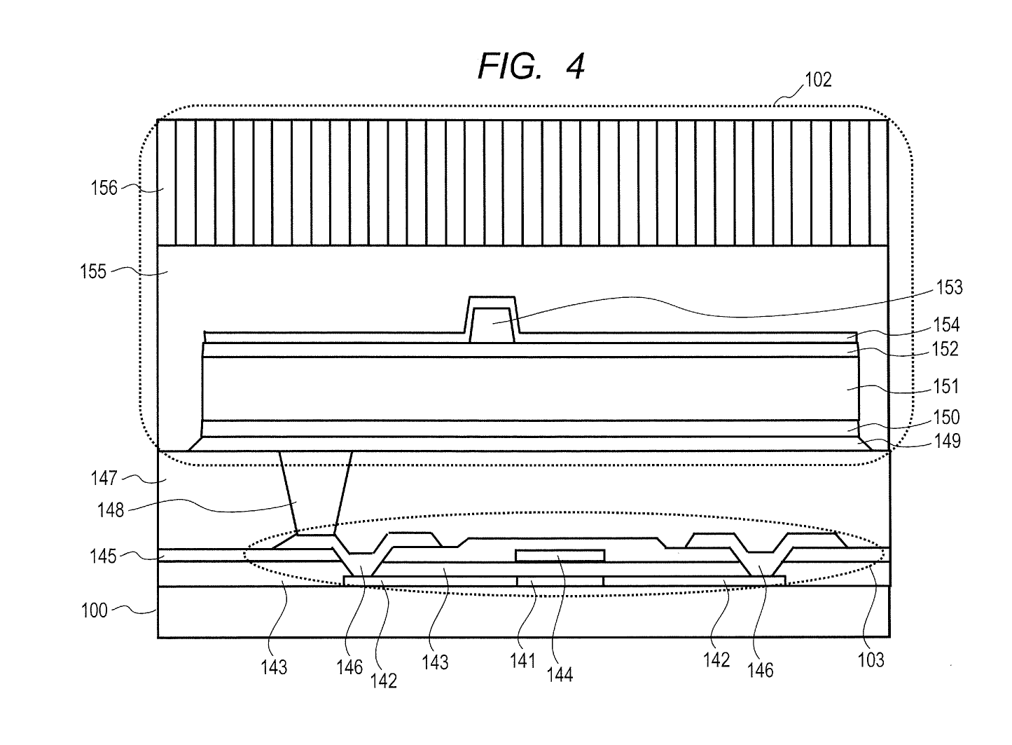

FIG. 3A is a top view showing an example of the pixel area 137, where part of the structure including the switching devices 103 have been extracted from an area containing 2×2 pixels. FIG. 4 is a sectional view taken along line 4-4 in FIG. 3A, showing a sectional structure of a pixel 101. In FIG. 3A, the drive lines 104a and 104b are placed at equal intervals and each pixel row has two drive lines 104a and 104b. The control electrodes of the switching devices 103 in the pixels arranged in the row direction are connected alternately to different drive lines 104a and 104b. According to the present embodiment, each pixel row includes two drive lines 104a and 104b, but a third drive line 104c may be further included as shown in FIG. 3B. In that case, the data lines 105 may be connected to a 1-to-3 multiplexer although detailed description is omitted.

Next, a sectional configuration of one pixel according to the present embodiment will be described with reference to FIG. 4. In the pixel 101, the conversion device 102 and switching device 103 are provided in one-to-one correspondence. The switching device 103 includes a first semiconductor layer 141, a first impurity semiconductor layer 142, a first insulating layer 143, a first conductive layer 144, a second insulating layer 145, and a second conductive layer 146, which are provided on the supporting substrate 100, such as a glass substrate, having an insulative surface. The first semiconductor layer 141 functions as a channel region of the TFT, the first impurity semiconductor layer 142 functions as a source or drain region, the first insulating layer 143 functions as a gate insulating film, the first conductive layer 144 functions as a gate electrode, and the second conductive layer 146 functions as a source or drain electrode. The gate electrode corresponds to the control electrode of the switching device 103 illustrated in FIG. 3A and is connected to one of the two drive lines. The source or drain electrode corresponds to the main electrode.

Incidentally, a staggered TFT is used in FIG. 4, in which polycrystalline silicon is used in the first semiconductor layer 141. If staggered TFTs with polycrystalline silicon are similarly used for the switches 132a and 132b in FIG. 2, the manufacturing process will be simplified. The conversion device 102 is placed on a third insulating layer 147 covering the switching device 103. The conversion device 102 is configured to include a fourth conductive layer 149, a second impurity semiconductor layer 150, a second semiconductor layer 151, a third impurity semiconductor layer 152, a fifth conductive layer 153, and a sixth conductive layer 154. The fourth conductive layer 149 functions as the first electrode by being coupled to the first main electrode of the switching device 103 via a third conductive layer 148. The second impurity semiconductor layer 150 has been doped with an n-type impurity and the third impurity semiconductor layer 152 has been doped with a p-type impurity. The second semiconductor layer 151 functions as a photoelectric conversion layer of a photoelectric conversion device, the fifth conductive layer 153 functions as the bias line 106, and the sixth conductive layer 154 functions as the second electrode. A scintillator 156 is provided on a fourth insulating layer 155 which covers the plural photoelectric conversion devices and functions as a planarizing layer. The conversion device 102 and switching device 103 can be formed appropriately using a vapor-phase growth (vapor deposition) process, an etching process, and photolithography techniques. Although a PIN photodiode which uses the second impurity semiconductor layer 150 as a photoelectric conversion device has been described in the present embodiment, the present embodiment is not limited to this and a MIS photosensor which uses an insulating layer instead of the second impurity semiconductor layer 150 may be adopted.

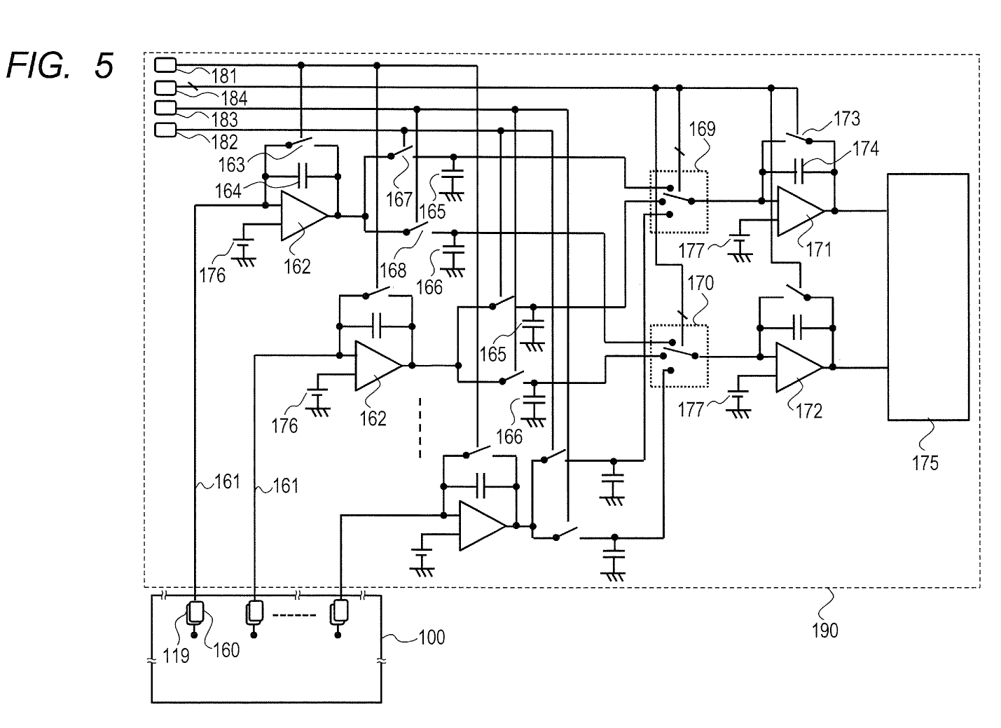

Next, part of the read circuit 190 of the detection apparatus will be described with reference to FIG. 5. In FIG. 5, only part of the connection terminal 119 of the supporting substrate 100 of FIG. 2 is illustrated and the connection terminal 119 is connected to a connection terminal 160 of the read circuit 190. Also, as part of the read circuit 190, a portion involved in converting an analog signal into a digital signal is shown partially.

Each connection terminal 160 is connected to an inverting input terminal of an operational amplifier 162 via a data line 161. The inverting input terminal of the operational amplifier 162 is connected to an output terminal via a reset switch 163 and storage capacitor 164 while a non-inverting input terminal is connected to a reference power supply 176. The reset switch 163 and storage capacitor 164 are connected between the output terminal and inverting input terminal of the operational amplifier 162. The output terminal of each operational amplifier 162 is connected to a signal sampling capacitor 165 and noise sampling capacitor 166 via a signal sample-and-hold switch 167 and noise sample-and-hold switch 168, respectively. The signal sample-and-hold switch 167 is a first sample-and-hold switch adapted to sample and hold the charge read out of the connection terminal 119 in the signal sampling capacitor (first sampling capacitor) 165. The noise sample-and-hold switch 168 is a second sample-and-hold switch adapted to sample and hold the charge read out of the connection terminal 119 in the noise sampling capacitor (second sampling capacitor) 166. Plural signal sampling capacitors 165 are connected to an inverting input terminal of a signal operational amplifier 171 via a signal multiplexer 169. Similarly, the plural noise sampling capacitors 166 are connected to an inverting input terminal of a noise operational amplifier 172 via a noise multiplexer 170.

The inverting input terminals of the signal operational amplifier 171 and noise operational amplifier 172 are connected to respective output terminals via respective reset switches 173 and storage capacitors 174 while the non-inverting input terminals are connected to reference power supplies 177, respectively. The output terminal of the signal operational amplifier 171 and output terminal of the noise operational amplifier 172 are differentially input in an analog-to-digital converter 175. A control line of the reset switch 163 is connected to a connection terminal 181. Control lines of the signal sample-and-hold switch 167 and noise sample-and-hold switch 168 are connected to a connection terminal 182 and connection terminal 183, respectively. A control line group used to control the signal multiplexer 169, noise multiplexer 170 and reset switch 173 is connected to a connection terminal group 184. The switches are controlled by control signals from the respective terminals to which the switches are connected.

Using correlated double sampling, the present embodiment is configured to be able to cancel out KTC noise generated when the reset switch 163 is closed. The read circuit 190 has an infinite number of possible configurations. The non-inverting input terminal of the operational amplifier 162 is electrically connected to the connection terminal 119 of the supporting substrate 100, and the reset switch 163 can be configured to be able to cause a short circuit between the non-inverting input terminal of the operational amplifier 162 and the output terminal. When turned on, the reset switch 163 supplies a constant potential to the connection terminal 119. As long as the KTC noise generated when the reset switch 163 is closed can be cancelled out or reduced by correlated double sampling, the configuration of the read circuit 190 is not limited to the one shown in FIG. 5.

Next, a configuration example of the detection apparatus 191 will be described with reference to FIGS. 1 and 2. The detection unit 193 includes the supporting substrate 100, the external drive circuit 192 and the read circuit 190. The supporting substrate 100 includes at least the pixel area 137 and multiplexer unit 131 shown in FIG. 2. The drive circuit 192 is electrically connected with the pixel area 137 via the connection terminals 107 on the supporting substrate 100 of FIG. 2 and adapted to control driving of the pixel area 137. The read circuit 190 is electrically connected with the pixel area 137 via the connection terminals 119 on the supporting substrate 100 of FIG. 2 and adapted to output electric signals from the pixel area 137 as image data. The drive circuit 192 outputs the voltages Vcom and Voff to the connection terminals 107 of FIG. 2. That is, the drive circuit 192 is designed to control a selected state and non-selected state of the pixels 101. The detection apparatus 191 further includes the signal processing unit 194 adapted to process and output the image data received from the detection unit 193, the control circuit 195 adapted to supply respective control signals to various components and control operation of the detection unit 193, and the power supply circuit 196 adapted to supply respective biases to the various components.

The control circuit 195 receives a control signal from a control computer (not shown) and provides a control signal to the signal processing unit 194. Also, the signal processing unit 194 receives electric-potential information about the data lines 105 from the read circuit 190 during an irradiation period and transmits the electric-potential information to the control computer (not shown). The power supply circuit 196 includes a regulator and the like adapted to receive a voltage from an external power supply or built-in battery (not shown) and supply necessary voltages to the supporting substrate 100, drive circuit 192 and read circuit 190. The power supply circuit 196 is electrically connected with the connection terminals 109. The control circuit 195 is electrically connected with the connection terminals 135 and 136 and adapted to output control signals. Incidentally, although the drive circuit 192, read circuit 190, signal processing unit 194, control circuit 195 and power supply circuit 196 are each represented by a single block, this does not mean that each of them is made up of one integrated circuit. Each of them may be made up of plural integrated circuits or all of them may be provided in a single integrated circuit. Besides, the above description is also applicable to other embodiments of the present invention as appropriate.

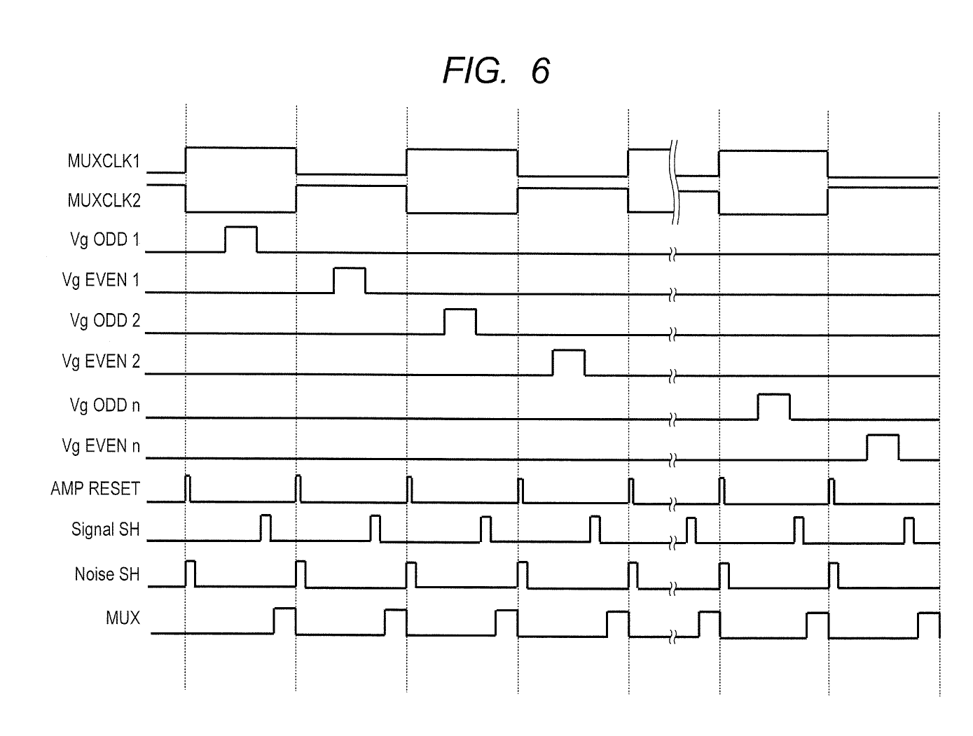

The process from when signal charges accumulated in the pixels 101 are read by operating the multiplexer unit 131 to when the signal charges are converted into digital data in the present embodiment will be described with reference to a timing chart in FIG. 6 as well as to FIGS. 1, 2 and 5.

First, signals in the timing chart shown in FIG. 6 and related to a detection apparatus drive method will be described. MUX CLK1 and MUX CLK2 represent states of voltages applied to the connection terminals 135 and 136 from the control circuit 195. Logic high means a voltage level at which a switch is turned on while a logic low means a voltage level at which the switch is turned off.

VgODD1 and VgEVEN1 represent states of voltages applied to the control electrodes of the switching devices 103 contained in the pixels 101 in the first row in FIG. 2 from the drive circuit 192 via the connection terminals 107. VgODD1 represents the state of voltage supplied to the connection terminal 107 connected to the drive line 104a for the pixels in the first row while VgEVEN1 represents the state of voltage supplied to the connection terminal 107 connected to the drive line 104b for the pixels in the first row. Similarly, VgODD2 and VgEVEN2 represent states of voltages applied to the control electrodes of the switching devices 103 contained in the pixels 101 in the second row in FIG. 2 from the drive circuit 192 via the connection terminals 107. VgODD2 represents the state of voltage supplied to the connection terminal 107 connected to the drive line 104a for the pixels in the second row while VgEVEN2 represents the state of voltage supplied to the connection terminal 107 connected to the drive line 104b for the pixels in the second row.

Also, VgODDn and VgEVENn represent states of voltages applied to the control electrodes of the switching devices 103 contained in the pixels 101 in the nth row in FIG. 2 via the connection terminals 107. VgODDn represents the state of voltage supplied to the connection terminal 107 connected to the drive line 104a for the pixels in the nth row while VgEVENn represents the state of voltage supplied to the connection terminal 107 connected to the drive line 104b for the pixels in the nth row. Logic high of VgODD1, VgEVEN1, VgODD2, VgEVEN2, VgODDn and VgEVENn means the voltage level at which the connected switching devices 103 are turned on while logic low means the voltage level at which the switching devices 103 are turned off.

AMP RESET represents a control signal which is input to a control terminal 181 from the control circuit 195, and logic high of AMP RESET represents a signal which turns on the connected reset switch 163 while logic low represents a signal which turns off the connected reset switch 163. That is, a logic high state resets voltages of the output terminals of the operational amplifiers 162 to a reference power supply 176.

Signal SH represents a control signal which is input to a control terminal 182 from the control circuit 195. Logic high of Signal SH means that a signal which turns on the connected signal sample-and-hold switch 167 is given while logic low of Signal SH means that a signal which turns off the connected signal sample-and-hold switch 167 is given. That is, at the logic high, the signal sampling capacitor 165 is charged to a potential equal to a potential of the output terminal of the operational amplifier 162.

Noise SH represents a control signal which is input to a control terminal 183 from the control circuit 195. Logic high of Noise SH means that a signal which turns on the connected noise sample-and-hold switch 168 is given while logic low of Noise SH means that a signal which turns off the connected noise sample-and-hold switch 168 is given. That is, at the logic high, the noise sampling capacitor 166 is charged to a potential equal to the potential of the output terminal of the operational amplifier 162.

MUX represents a period during which a control signal is input to a control terminal group 184 from the control circuit 195. During a logic high period, the signal multiplexer 169 and noise multiplexer 170 operate and the plural signal sampling capacitors 165 become electrically continuous with the inverting input terminal of the signal operational amplifier 171 one after another by switching among themselves. At the same time, the plural noise sampling capacitors 166 become electrically continuous with the inverting input terminal of the noise operational amplifier 172 one after another by switching among themselves to perform so-called multiplexed operations.

The multiplexers 169 and 170 operate such that the signal sampling capacitor 165 and noise sampling capacitor 166 connected to the output terminal of the same operational amplifier 162 will simultaneously be made electrically continuous with the signal operational amplifier 171 and noise operational amplifier 172, respectively. Before switching to a different signal sampling capacitor 165 and noise sampling capacitor 166, the reset switch 173 is temporarily turned on to reset output terminal voltages of the operational amplifiers 171 and 172 to a reference power supply 177.

Also, during the logic high period, output potentials of the signal operational amplifier 171 and noise operational amplifier 172 are differentially input to an analog-to-digital converter 175 and converted into digital data. The digital data is sent to the signal processing unit 194 and is subjected to image processing as two-dimensional image information. On the other hand, during a logic low period of MUX, the signal multiplexer 169 and noise multiplexer 170 are not connected to either of the signal sampling capacitor 165 and noise sampling capacitor 166.

In the timing chart in FIG. 6, first, MUX CLK1 goes logic high, turning on the switches 132a connected to the drive line 133. The KTC noise generated when the switches 132a were closed the last time has been accumulated on the data lines 105, and when the data line 105 and connection terminal 119 become electrically continuous with each other, the KTC noise is transferred to the operational amplifier 162. Also, AMP RESET goes logic high, turning on the reset switch 163. Also, Noise SH goes logic high, turning on the noise sample-and-hold switch 168. Consequently, the KTC noise flows to the output terminal of the operational amplifier 162 and disappears as information.

When the reset switch 163 turns on, KTC noise is accumulated in the storage capacitor 164 and a charge corresponding to the KTC noise is accumulated in the noise sampling capacitor 166. Next, AMPRESET goes logic low, turning off the reset switch 163.

Next, Noise SH goes logic low, turning off the noise sample-and-hold switch 168. Subsequently, VgODD1 goes logic high, turning on the switching devices 103 of the pixels 101 in the odd-numbered columns of the first row. Consequently, out of the pixels 101 in the first row, signal charges are transferred from the pixels 101 in the odd-numbered columns and accumulated in the storage capacitor 164 by adding to the KTC noise of the reset switch 163, the odd-numbered columns being electrically continuous with the inverting input terminal of the operational amplifier 162. On the other hand, regarding those pixels 101 in the first row which are not electrically continuous with the inverting input terminal of the operational amplifier 162 due to the logic low of MUX CLK2, signal charges can be held in the pixels 101 because VgEVEN1 is logic low at the same time.

Next, VgODD1 goes logic low, turning off the switching devices 103 of the pixels 101 in the odd-numbered columns of the first row. Next, Signal SH goes logic high, turning on the signal sample-and-hold switch 167. Consequently, based on the electric charges accumulated in the storage capacitor 164, the signal sampling capacitor 165 is charged according to KTC noise as well as the signal charges from the pixels 101.

Next, Signal SH goes logic low, turning off the signal sample-and-hold switch 167. Subsequently, during a logic high period of MUX, digital signals are obtained one after another according to differences between the quantity of the electric charge accumulated in the signal sampling capacitors 165 and that accumulated in the noise sampling capacitors 166. Consequently, signals are acquired from the pixels 101 connected to one drive line 104a or 104b.

Next, MUX CLK1 goes logic low, turning off the switches 132a connected to the drive line 133. Subsequently, MUX CLK2 goes logic high, turning on the switches 132b connected to the drive line 134. The KTC noise generated when the switches 132b were closed the last time has been accumulated on the data lines 105, and when the data line 105 and connection terminal 119 become electrically continuous with each other, the KTC noise is transferred to the operational amplifier 162. Also, AMP RESET goes logic high, turning on the reset switch 163. Also, Noise SH goes logic high, turning on the noise sample-and-hold switch 168. Consequently, the KTC noise flows to the output terminal of the operational amplifier 162 and disappears as information.

When the reset switch 163 turns on, KTC noise is accumulated in the storage capacitor 164 and a charge corresponding to the KTC noise is accumulated in the noise sampling capacitor 166. Next, AMPRESET goes logic low, turning off the reset switch 163.

Next, Noise SH goes logic low, turning off the noise sample-and-hold switch 168. Subsequently, VgEVEN1 goes logic high, turning on the switching devices 103 of the pixels 101 in the even-numbered columns of the first row. Consequently, out of the pixels 101 in the first row, signal charges are transferred from the pixels 101 in the even-numbered columns and accumulated in the storage capacitor 164 by adding to the KTC noise of the reset switch 163, the even-numbered columns being electrically continuous with the inverting input terminal of the operational amplifier 162.

Next, VgEVEN1 goes logic low, turning off the switching devices 103 of the pixels 101 in the even-numbered columns of the first row. Next, Signal SH goes logic high, turning on the signal sample-and-hold switch 167. Consequently, based on the electric charges accumulated in the storage capacitor 164, the signal sampling capacitor 165 is charged according to KTC noise as well as the signal charges from the pixels 101.

Next, Signal SH goes logic low, turning off the signal sample-and-hold switch 167. Subsequently, during a logic high period of MUX, digital signals are obtained one after another according to differences among quantities of electric charge accumulated in the signal sampling capacitors 165 and noise sampling capacitors 166. Consequently, signals are acquired from the pixels 101 connected to one drive line 104a or 104b. Subsequently, MUX CLK2 goes logic low, turning off the switches 132b connected to the drive line 134.

Subsequently, the operation described above is repeated. As a feature of the present embodiment, when MUX CLK2 goes logic high, those pixels 101 in the first row which are electrically continuous with the inverting input terminal of the operational amplifier 162 hold signal charges. Also, even when AMP RESET goes logic high at the same time, only the KTC noise generated when the switches 132a and 132b were closed the last time disappears and the signal charges are held as information in the pixels 101.

The operation described above allows the signal charges accumulated in the pixels 101 of the first row to be read out and converted into digital data. The above operation is repeated to convert the signal charges of the pixels 101 in the second to nth rows into digital data in sequence.

Through the series of actions, the KTC noise generated by the switches 132a and 132b in the multiplexer unit 131 is erased by turning on the reset switch 163 of the operational amplifier 162. In so doing, to avoid erasing signal charges at the same time, the switching devices 103 of the pixels 101 and data lines 105 connected to non-conducting switches 132a or 132b are kept off using the above configuration and operation timing. Also, the KTC noise generated by the reset switch 163 is cancelled out by so-called correlated double sampling.

Capacitance of the data lines 105 increases with increasing size of the pixel area 137, and the KTC noise generated by the switches 132a and 132b increases accordingly. The present embodiment can almost halve the number of connection terminals 119 using the multiplexer unit 131. Also, KTC noise in signal charges can be erased selectively. Besides, the above description is also applicable to other embodiments of the present invention as appropriate.

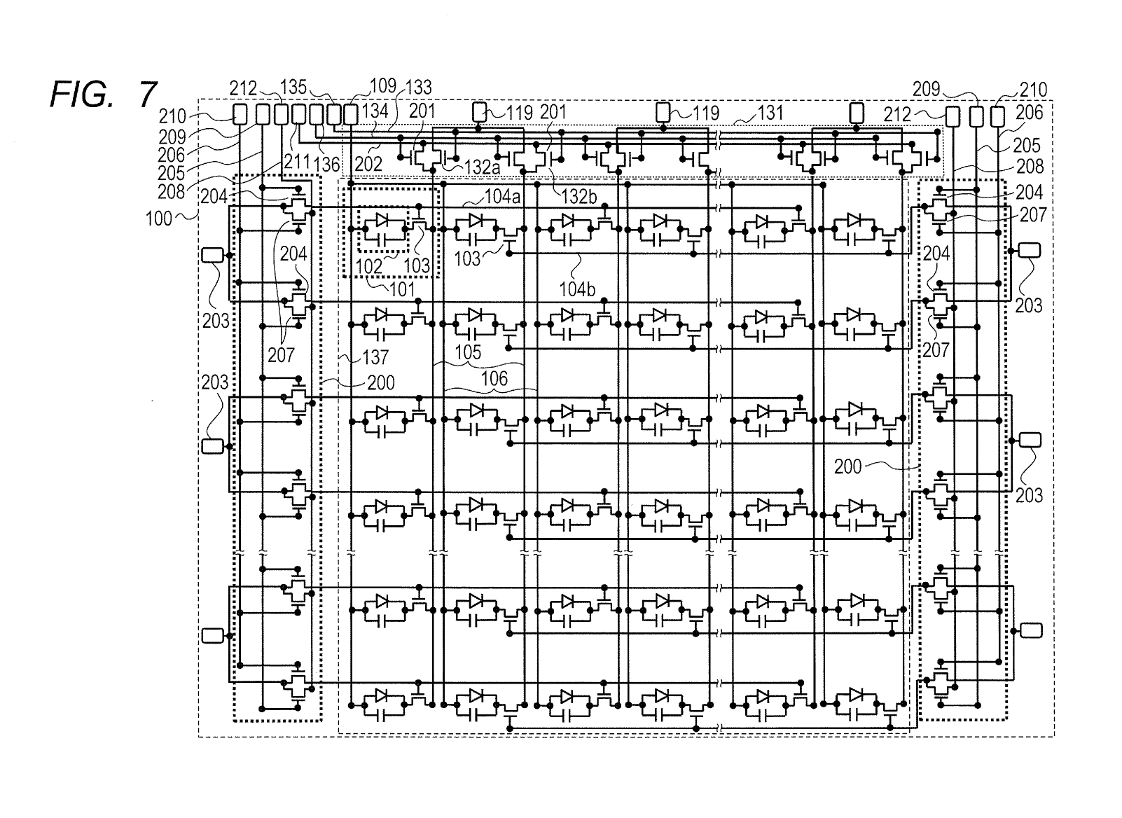

FIG. 7 shows another configuration example of the detection apparatus according to the present embodiment. The detection apparatus in FIG. 7 differs from that in FIG. 2 in that to reduce the number of connection terminals 107 connected to the drive lines 104a and 104b, the drive lines 104a and 104b are connected to demultiplexer units 200 placed on left and right sides of the pixel area 137. Also, when the switches 132a and 132b of the multiplexer unit 131 are electrically cut off from the data lines 105, an electrical impact on surrounding pixels due to floating of the data lines 105 can be avoided. For that, while the connection terminals 119 and data lines 105 are not electrically continuous with each other, the data lines 105 are configured to be fixed to a reference potential line 202 by switching devices 201. The reference potential line 202 is equal in potential to the reference power supply 176 in FIG. 5.

In FIG. 7, drive lines are electrically connected to the external drive circuit 192 shown in FIG. 1 via connection terminals 203 placed on left and right sides of the pixel area 137. The number of connection terminals 203 is smaller than the number of drive lines, i.e., the number of pixel rows in an effective pixel area. At two locations on the left and right sides, the demultiplexer units 200 are placed between the plural connection terminals 203 and plural drive lines 104a and 104b placed on the left and right sides of the pixel area 137. The plural demultiplexer units 200 are placed on opposite ends of the drive lines 104a and 104b. Each of the plural demultiplexer units 200 is connected with plural drive circuits 192 (FIG. 1). The demultiplexer unit 200 includes two switching devices 204 provided between one connection terminal 203 and two or more corresponding drive lines, the two switching devices 204 being provided in one-to-one correspondence with two drive lines. A first main electrode of the switching device 204 is connected to the drive lines 104a and 104b while a second main electrode is electrically continuous with the connection terminal 203. Also, a control terminal of the switching device 204 is connected to one of the control line 205 and control line 206 and is controlled by a control signal from the connected control line 205 or 206. Specifically, the drive lines 104a and 104b in the odd-numbered rows are connected to the demultiplexer unit 200 on the left side in FIG. 7 while the drive lines 104a and 104b in the even-numbered rows are connected to the demultiplexer unit 200 on the right side in FIG. 7. The control line connected to the switching devices 103 of the pixels 101 placed in the odd-numbered rows in the pixel area 137 is connected to the switching devices 204 connected to the control line 205. On the other hand, the control line connected to the switching devices 103 of the pixels 101 placed in the even-numbered rows in the pixel area 137 is connected to the switching devices 207 connected to the control line 206.

Also, the drive line is connected to a first main electrode of the switching device 207. A second main electrode of the switching device 207 is connected to an off-potential line 208 while a control electrode of the switching device 207 is connected with the control line 205 or control line 206. When the switching device 207 is controlled to be kept on, the drive lines 104a and 104b are clamped to the potential of the off-potential line 208. The control electrodes of the switching devices 204 and 207 whose first main electrodes are connected to one drive line 104a or 104b are connected to different ones of the control lines 205 and 206, respectively.

The control line 205, control line 206, reference potential line 202 and off-potential line 208 are connected to a connection terminal 209, connection terminal 210, connection terminal 211 and connection terminal 212, respectively. The connection terminals including the connection terminal 203 are placed between an edge of the supporting substrate 100 and the pixel area 137. The rest of the configuration is similar to the one shown in FIG. 2.

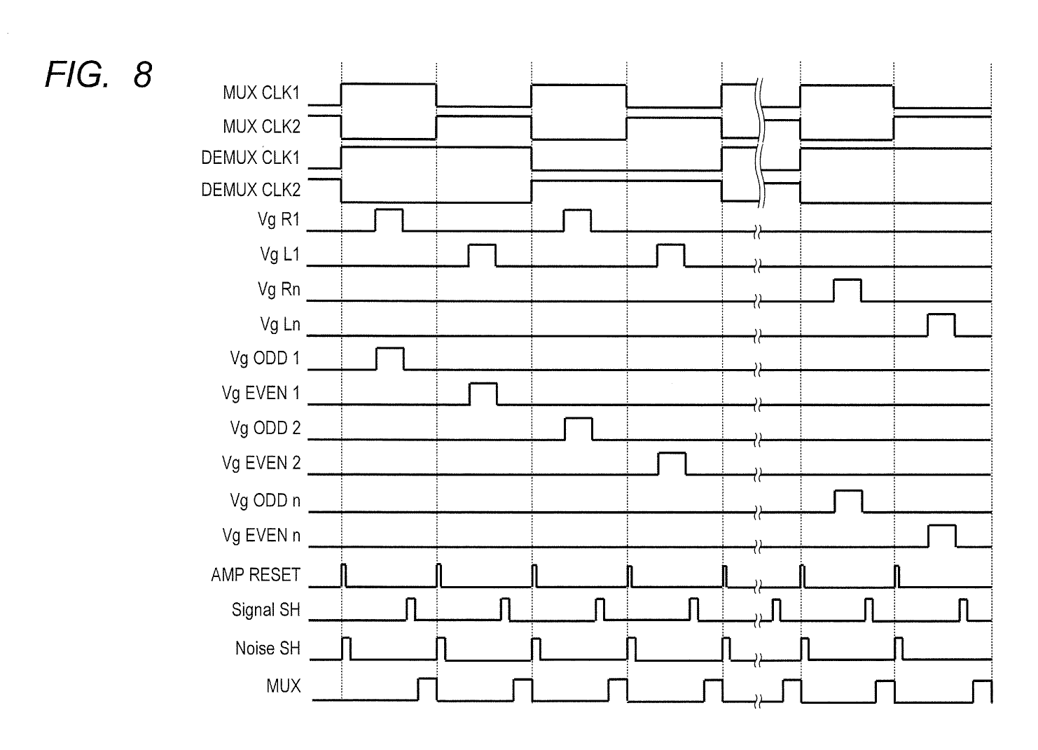

The process from when the signal charges accumulated in the pixels 101 are read by operating the multiplexer unit 131 and demultiplexer units 200 to when the signal charges are converted into digital data in the configuration of FIG. 7 is shown in a timing chart of FIG. 6. Except for operation of the demultiplexer units 200, the timing chart of FIG. 8 is similar to that of FIG. 6. Only the signals added in FIG. 8 will be described here.

DEMUX CLK1 and DEMUX CLK2 represent control signals intended for the switching devices 204 connected via the connection terminal 209 and connection terminal 210, respectively. When the control signals are logic high, the switching devices 204 turn on. That is, the drive lines 104a and 104b become electrically continuous with the connection terminal 203 or off-potential line 208. When the control signals are logic low, the switching devices 204 turn off.

VgR1 and VgRn represent control signals which are input to the connection terminals 203 for the first row and nth row out of the connection terminals 203 connected to the demultiplexer unit 200 on the right side in FIG. 7. Logic high of the control signals gives a voltage at which the switching devices 103 turn on. That is, when the connection terminals 203 are electrically continuous with drive lines, the signal charges of the pixels 101 connected to the drive lines are transferred to the data lines 105 when the switching devices 103 turn on. On the other hand, logic low of the control signals gives a voltage at which the switching devices 103 turn off.

Similarly, VgL1 and VgLn represent control signals which are input to the connection terminals 203 for the first row and nth row out of the connection terminals 203 connected to the demultiplexer unit 200 on the left side in FIG. 7. Regarding the logic high and logic low states, the description of VgR1 and VgRn similarly apply to VgL1 and VgLn. The timing chart of FIG. 6 similarly applies to the operation in the pixel area 137 and operation in the read circuit 190.

As a feature of the configuration in FIG. 7, the drive lines 104a and 104b are connected to the connection terminals 203 via the demultiplexer units 200. Consequently, placement intervals of the connection terminals 119 can be made approximately equal to placement intervals of the connection terminals 203, allowing placement density of the connection terminals to be approximately halved compared to when no multiplexer or demultiplexer is used. This allows the connection terminals to be mounted even when the pixels 101 are arranged at higher density. Also, since the potential of the data lines 105 is clamped at the potential of the reference power supply 176 without floating, an electrical impact on surrounding pixels can be avoided.

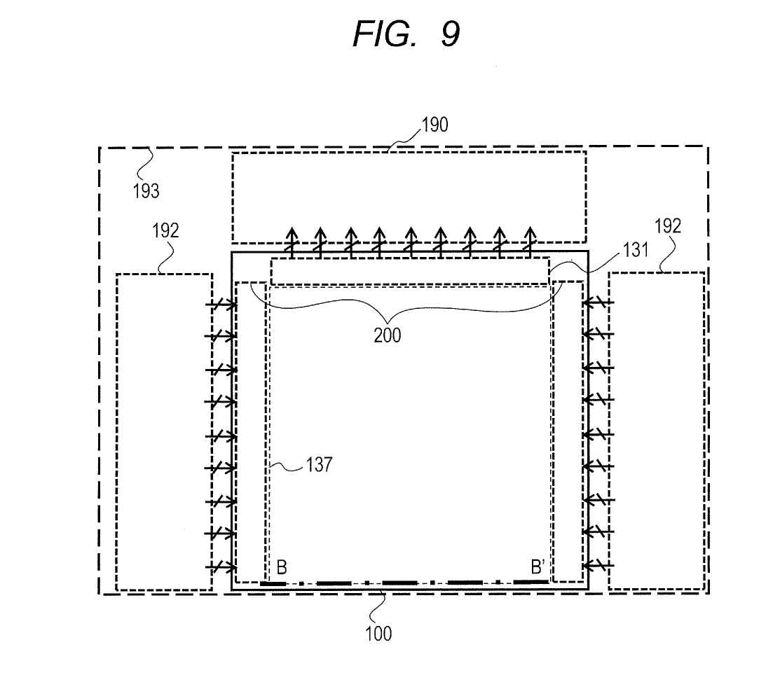

FIG. 9 is a diagram showing a configuration example of the detection unit 193 equipped with the supporting substrate 100 shown in FIG. 7. The read circuit 190 and two drive circuits 192 are mounted on three sides of the supporting substrate 100. The remaining one side of the supporting substrate 100 is placed close to an edge of the detection unit 193. That is, on one side, the pixel area 137 capable of detecting radiation extends to the edge of the detection unit 193. In FIG. 9, the pixel area 137 is placed up to side B-B′. The detection apparatus including the detection unit 193 of FIG. 9 can be used for mammography. This is advantageous because during radiography of a patient's breast portion, side B-B′ is placed closer to the patient, extending radiographic coverage. Furthermore, the present embodiment, which allows the pixels 101 to be placed at high density, provides an optimal form for mammography which requires high-definition radiographic images.

### Second Embodiment

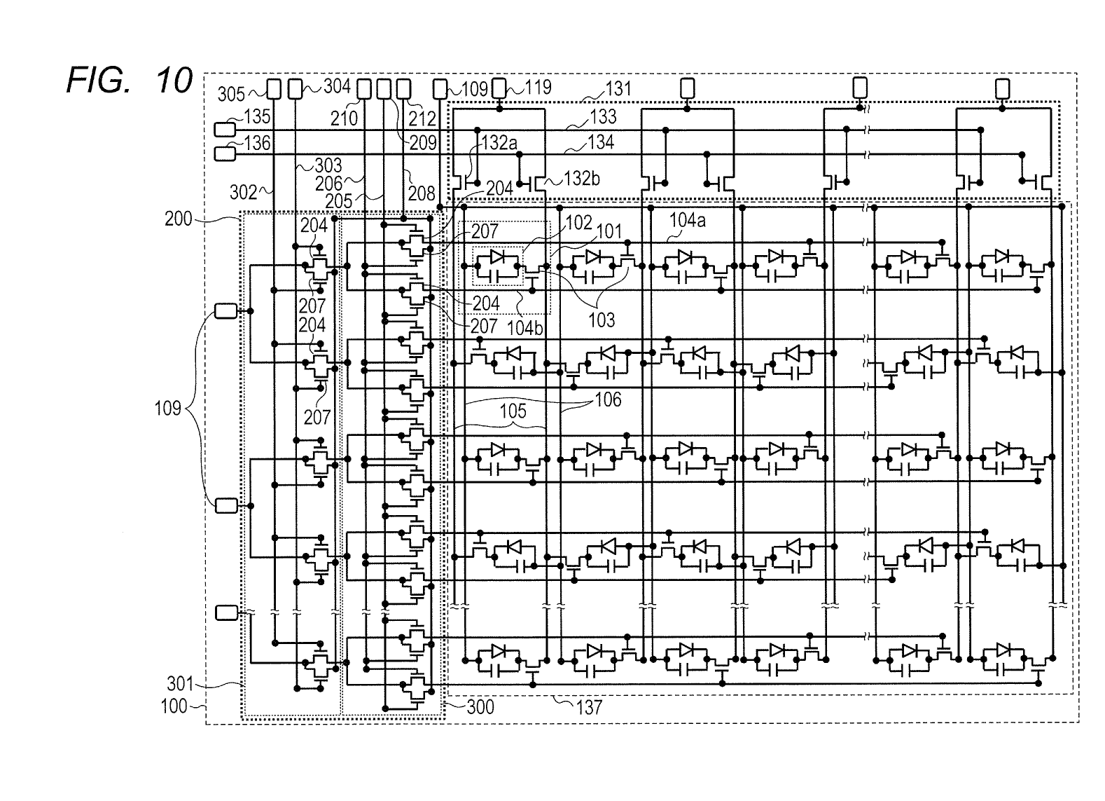

FIG. 10 is an equivalent circuit diagram for illustrating a detection apparatus according to a second embodiment of the present invention. The configuration in FIG. 10 differs from FIG. 2 in that the pixels 101 connected to any one data line 105 via the switching devices 103 are not placed adjacently in the column direction, but alternately. On the other hand, as with FIG. 2, the control electrodes of the plural switching devices 103 in the pixels 101 arranged in one row are electrically connected with one of the two drive lines 104a and 104b. Out of the switching devices 103 which can be made electrically continuous with one connection terminal 119 via two switches 132a and 132b, the switching devices 103 of two pixels 101 adjacent to a same row are connected to different drive lines 104a and 104b, respectively.

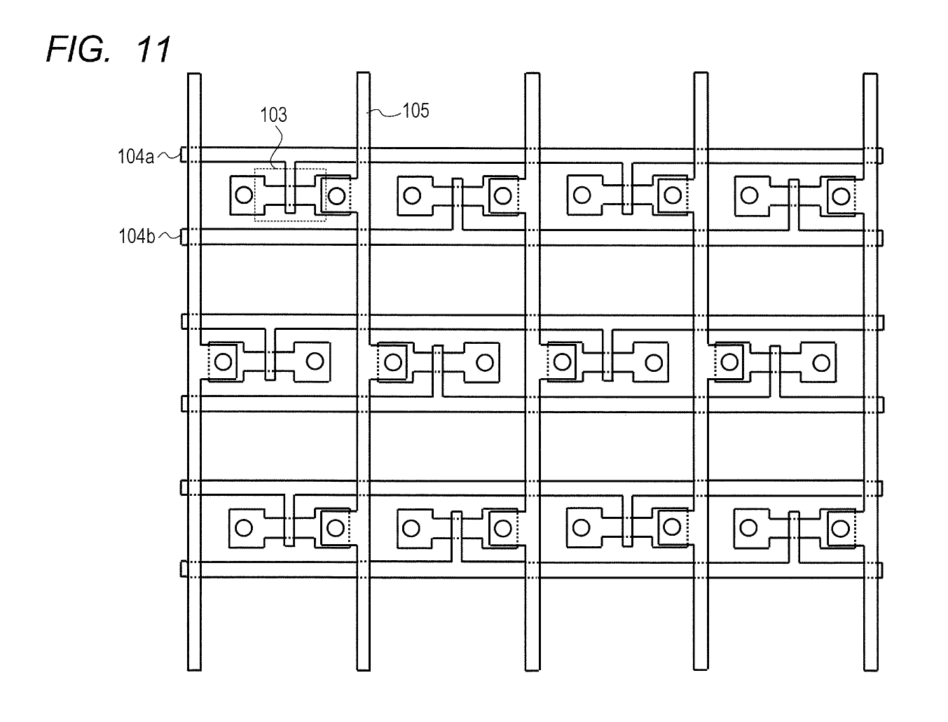

FIG. 11 is a top view showing an example of the actual pixel area 137 according to the present embodiment, where part of the structure including the switching devices 103 have been extracted from an area containing 3×4 pixels. In FIG. 11, the drive lines 104a and 104b are placed at equal intervals and each pixel row has two drive lines 104a and 104b. The control electrodes of the switching devices 103 in the pixels arranged in the row direction are connected alternately to different drive lines 104a and 104b. Also, the second main electrodes of the switching devices 103 in the pixels arranged in the column direction are connected alternately to different data lines 105.

In FIG. 10, the demultiplexer unit 200 is configured such that two stages of 1-to-2 demultiplexers are arranged in series. Here, for the sake of convenience, a multiplexer unit directly connected to the drive lines 104a and 104b will be referred to as a first-stage multiplexer 300 and a multiplexer unit directly connected to the connection terminals 109 will be referred to as a second-stage multiplexer 301. The switching devices 204 in the first-stage multiplexer 300 and second-stage multiplexer 301 connected in series are connected between the drive lines 104a and 104b and the connection terminals 109. Also, the off-potential line 208 can be made electrically continuous with the drive lines 104a and 104b in both the first-stage multiplexer 300 and second-stage multiplexer 301 via the switching device 207. Control lines of the switching devices 204 and 207 in the first-stage multiplexer 300 are connected to the control line 205 and control line 206, respectively. Control lines of the switching devices 204 and 207 in the second-stage multiplexer 301 are connected to a control line 302 and control line 303, respectively. The control line 205, control line 206, control line 302 and control line 303 are connected to the connection terminal 209, the connection terminal 210, a connection terminal 304 and a connection terminal 305, respectively, and all the connection terminals are placed between an edge of the supporting substrate 100 and the pixel area 137.

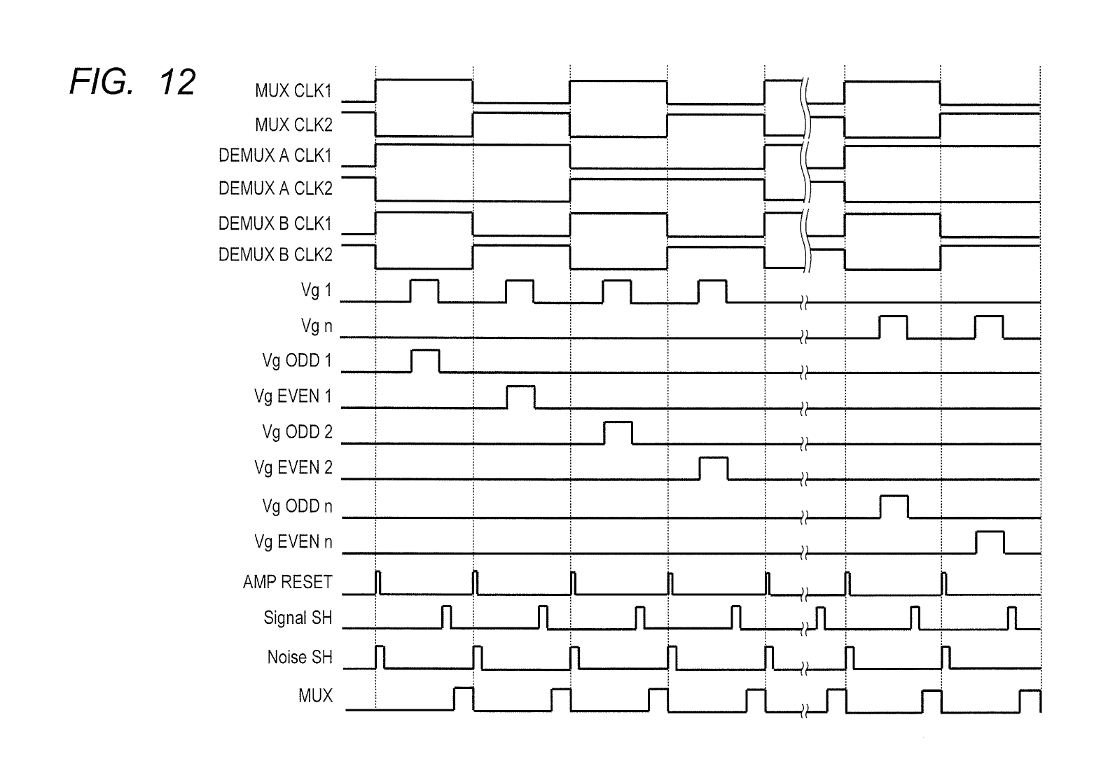

An example of the process from when the signal charges accumulated in the pixels 101 is read by operating the multiplexer unit 131 to when the signal charges are converted into digital data in the present embodiment is shown in a timing chart of FIG. 12. First, signals in the timing chart shown in FIG. 12 will be described with reference to FIGS. 5, 10 and 11.

MUX CLK1 and MUX CLK2 represent states of voltages applied to the connection terminals 135 and 136. Logic high of MUX CLK1 and MUX CLK2 means the voltage level at which the connected switches 132a and 132b are turned on while logic low means the voltage level at which the connected switches 132a and 132b are turned off. DEMUX A CLK1 and DEMUX A CLK2 represent states of voltages applied to the connection terminal 304 and connection terminal 305. Logic high of DEMUX A CLK1 and DEMUX A CLK2 means the voltage level at which the switching devices 204 or switching devices 207 in the connected second-stage multiplexer 301 are turned on while logic low means the voltage level at which the switching devices 204 or switching devices 207 in the connected second-stage multiplexer 301 are turned off. Similarly, DEMUX B CLK1 and DEMUX B CLK2 represent states of voltages applied to the connection terminal 209 and connection terminal 210. Logic high of DEMUX B CLK1 and DEMUX B CLK2 means the voltage level at which the switching devices 204 or switching devices 207 in the connected first-stage multiplexer 300 are turned on while logic low means the voltage level at which the switching devices 204 or switching devices 207 in the connected first-stage multiplexer 300 are turned off.

Vg1 and Vgn represent voltages applied to the connection terminals 109 in the first row and nth row. Logic high of Vg1 and Vgn means the voltage level at which the switching devices 103 are turned on when the switching devices 204 are on and logic low of Vg1 and Vgn means the voltage level at which the switching devices 103 are turned off when the switching devices 204 are on. VgODD1 and VgEVEN1 represent states of voltages applied to the control electrodes of the switching devices 103 contained in the pixels 101 in the first row in FIG. 10 via the demultiplexer unit 300. VgODD1 represents a state of voltage supplied to the drive line 104a of the pixels in the first row while VgEVEN1 represents a state of voltage supplied to the drive line 104b of the pixels in the first row. Similarly, VgODD2 and VgEVEN2 represent states of voltages applied to the control electrodes of the switching devices 103 contained in the pixels 101 in the second row in FIG. 10 via the demultiplexer unit 300. VgODD2 represents a state of voltage supplied to the drive line 104a of the pixels in the second row while VgEVEN2 represents a state of voltage supplied to the drive line 104b of the pixels in the second row.

Also, VgODDn and VgEVENn represent states of voltages applied to the control electrodes of the switching devices 103 contained in the pixels 101 in the nth row in FIG. 10 via the demultiplexer unit 300. VgODDn represents a state of voltage supplied to the drive line 104a of the pixels in the nth row while VgEVEN2 represents a state of voltage supplied to the drive line 104b of the pixels in the nth row. Logic high of VgODD1, VgEVEN1, VgODD2, VgEVEN2, VgODDn and VgEVENn means the voltage level at which the switching devices 103 connected to the respective drive lines are turned on while logic low means the voltage level at which the switching devices 103 connected to the respective drive lines are turned off. AMP RESET, Signal SH, Noise SH and MUX have functions similar to those of the first embodiment. Operation of the timing chart shown in FIG. 12 is similar to operation of the timing chart shown in FIG. 6 except for operations of the demultiplexer unit 300 and demultiplexer unit 301.

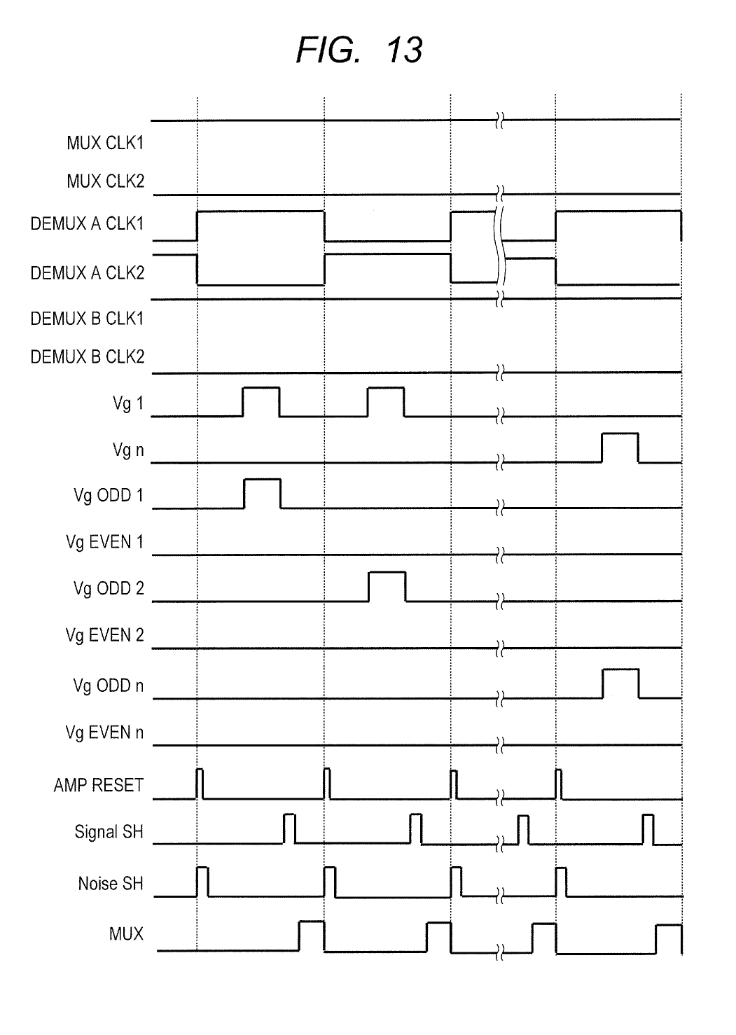

A timing chart shown in FIG. 13 is an example of the process of reading signal charges accumulated in the pixels 101 by operating the multiplexer unit 131. A feature of the timing chart shown in FIG. 13 is that MUX CLK1 is fixed at logic high with MUX CLK2 fixed at logic low. That is, the multiplexer unit 131 is not operated for a fixed period of time.

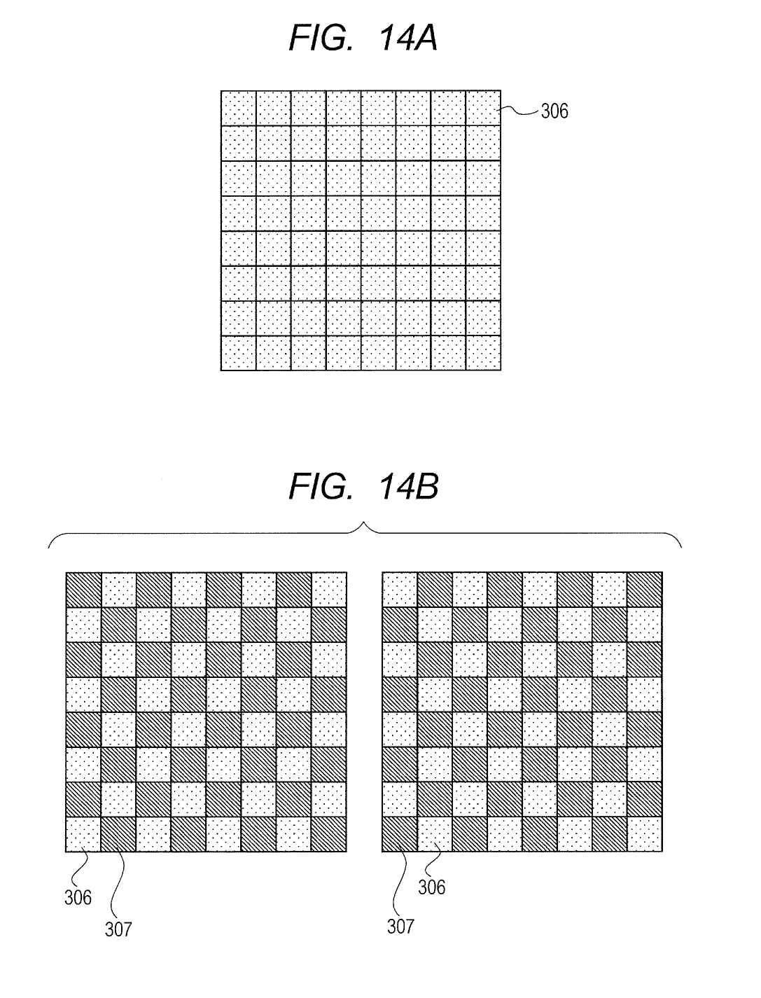

FIGS. 14A and 14B are diagrams showing imaginary image output according to the present embodiment, where output of an 8×8 array of pixels 101 has been extracted. The pixels which can provide output when the detection apparatus is operated with predetermined timing are designated as output pixels 306 and the pixels which cannot provide output are designated as non-output pixels 307. With the timing chart of FIG. 12, all the pixels can provide output, as in the case of FIG. 14A. On the other hand, with the timing chart of FIG. 13, the pixels in every other row and every other column can provide output, as in the case of FIG. 14B.

The present embodiment allows the placement density of the connection terminals to be approximately halved compared to when no multiplexer or demultiplexer is used. Also, half of the pixels can be read selectively at high speed.

### Third Embodiment

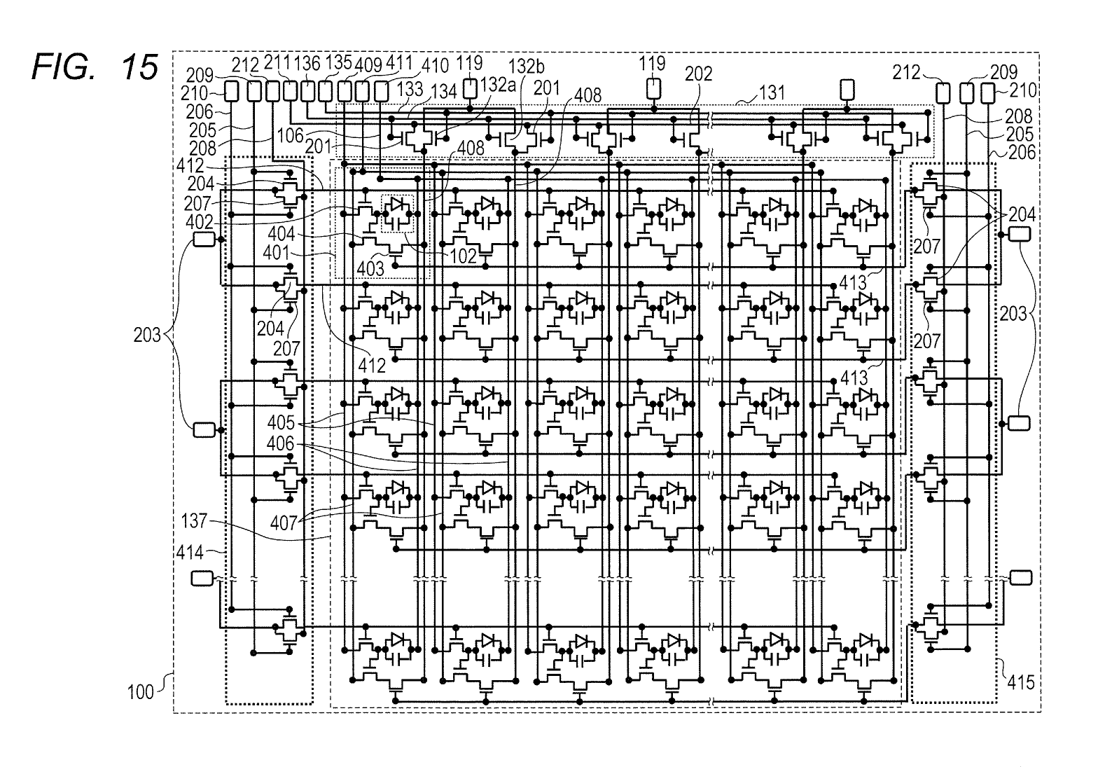

FIG. 15 is an equivalent circuit diagram for illustrating a detection apparatus according to a third embodiment of the present invention. In the first and second embodiments, only the switching device 103 and conversion device 102 are placed in the pixel 101. On the other hand, a pixel 401 according to the present embodiment contains a reset switch device 402, a pixel-select switch device 403, an amplifying switching device 404 and the conversion device 102.

The second electrode of the conversion device 102 is connected to a sensor bias line 406 while the first electrode of the conversion device 102 is connected to a first main electrode of the reset switch device 402 and a controlling terminal of the amplifying switching device 404. A second main electrode and control electrode of the reset switch device 402 are connected to a reset bias line 405 and reset switch drive line 412, respectively. A first main electrode and second main electrode of the amplifying switching device 404 are connected to a pixel bias line 407 and to a first main electrode of the pixel-select switch device 403. A second main electrode and control electrode of the pixel-select switch device 403 are connected to a data line 408 and select switch drive line 413. The reset bias line 405, sensor bias line 406 and pixel bias line 407 are supplied externally with electric power via a connection terminal 409, connection terminal 410 and connection terminal 411, respectively. Also, the reset switch drive line 412 is supplied with a drive voltage from a demultiplexer unit 414 on the left side in FIG. 15 while the select switch drive line 413 is supplied with a drive voltage from a demultiplexer unit 415 on the right side in FIG. 15.

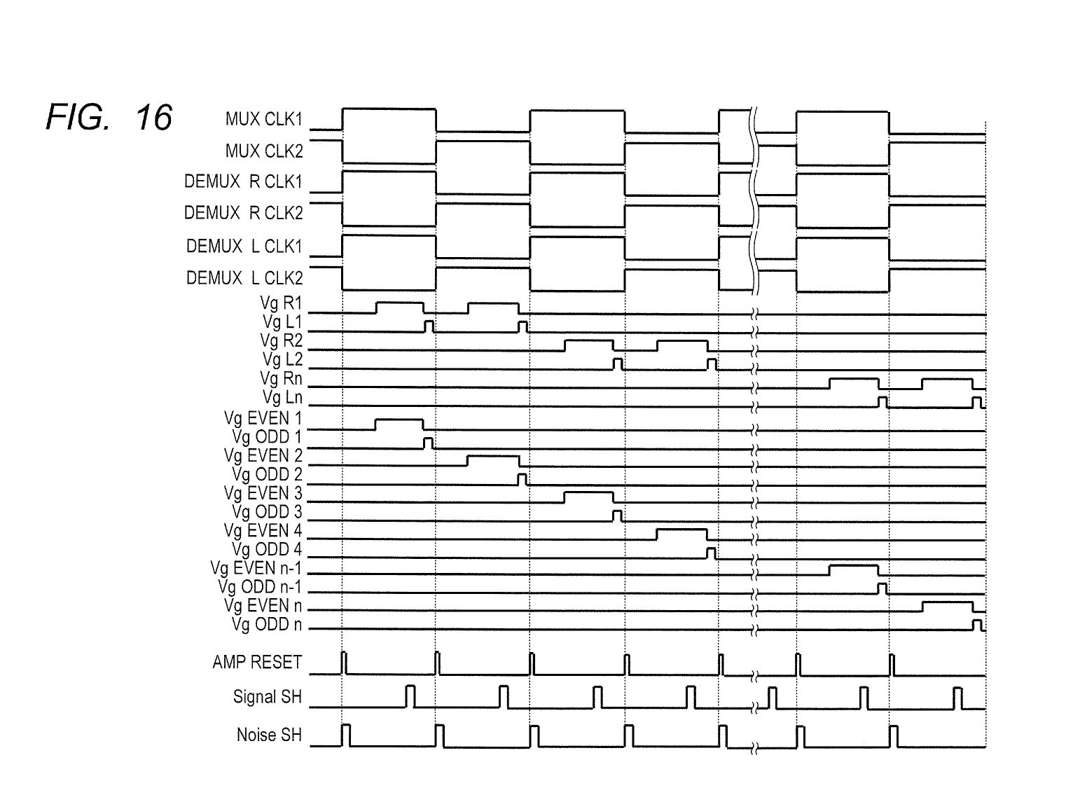

FIG. 16 is a timing chart according to the present embodiment. MUX CLK1 and MUX CLK2 represent states of voltages applied to the connection terminals 135 and 136. Logic high of MUX CLK1 and MUX CLK2 means the voltage level at which the connected switches 132a and 132b or switching devices 201 are turned on while logic low of MUX CLK1 and MUX CLK2 means the voltage level at which the connected switches 132a and 132b or switching devices 201 are turned off. DEMUX R CLK1 and DEMUX R CLK2 represent states of voltages applied to the multiplexer unit 415, connection terminal 209 and connection terminal 210. Logic high of DEMUX R CLK1 and DEMUX R CLK2 means the voltage level at which the switching devices 204 or switching devices 207 in the connected multiplexer unit 415 are turned on while logic low means the voltage level at which the switching devices 204 or switching devices 207 in the connected multiplexer unit 415 are turned off. Similarly, DEMUX L CLK1 and DEMUX L CLK2 represent states of voltages applied to the connection terminal 209 and connection terminal 210. Logic high of DEMUX L CLK1 and DEMUX L CLK2 means the voltage level at which the switching devices 204 or switching devices 207 in the connected multiplexer unit 414 are turned on while logic low means the voltage level at which the switching devices 204 or switching devices 207 in the connected multiplexer unit 414 are turned off.

VgR1, VgR2 and VgRn represent voltages applied to the connection terminals 203 in the first, second and nth rows, connected to the multiplexer units 415. Logic high of VgR1, VgR2 and VgRn means the voltage level at which the pixel-select switch devices 403 are turned on when the switching devices 204 are on and logic low of VgR1, VgR2 and VgRn means the voltage level at which the pixel-select switch devices 403 are turned off when the switching devices 204 are on. VgL1, VgL2 and VgLn represent voltages applied to the connection terminals 203 in the first, second and nth rows, connected to the multiplexer units 414. Logic high of VgL1, VgL2 and VgLn means the voltage level at which the reset switch devices 402 are turned on when the switching devices 204 are on and logic low of VgL1, VgL2 and VgLn means the voltage level at which the reset switch devices 402 are turned off when the switching devices 204 are on.

VgODD1, VgODD2, VgODD3, VgODDn−1 and VgODDn represent states of voltages applied to control electrodes of the reset switch devices 402 in the pixels 401 via the demultiplexer unit 414. VgODD1, VgODD2, VgODD3, VgODDn−1 and VgODDn represent the states of voltages supplied to the reset switch drive lines 412 of the first, second, third, (n−1)th and nth rows, respectively. Similarly, VgEVEN1, VgEVEN2, VgEVEN3, VgEVENn−1 and VgEVENn represent states of voltages applied to control electrodes of the pixel-select switch devices 403 in the pixels 401 via the demultiplexer unit 415. VgEVEN1, VgEVEN2, VgEVEN3, VgEVENn−1 and VgEVENn represent the states of voltages supplied to the select switch drive lines 413 of the first, second, third, (n−1)th and nth rows, respectively. AMP RESET, Signal SH, Noise SH and MUX have functions similar to those of the first embodiment.

The process from when signal charges accumulated in the pixels 401 are read by operating the multiplexer unit 131 to when the signal charges are converted into digital data in the present embodiment will be described with reference to timing charts in FIGS. 15 and 16 as well as to FIG. 5.

Referring to the timing chart in FIG. 16, first, MUX CLK1 goes logic high, turning on the switching devices 132a connected to the drive line 133. The KTC noise generated when the switches 132a were closed the last time has been accumulated on the data lines 105, and when the data line 105 and connection terminal 119 become electrically continuous with each other, the KTC noise is transferred to the operational amplifier 162. AMP RESET and Noise SH go logic high simultaneously, causing noise charges to flow to the output terminal of the operational amplifier 162 and disappear as information.

Next, AMP RESET goes logic low. As the reset switch 163 is closed, KTC noise is accumulated in the storage capacitor 164 and a charge corresponding to the KTC noise is accumulated in the noise sampling capacitor 166.

After Noise SH goes logic low, VgEVEN1 goes logic high. Consequently, a current corresponding to signal charges from those pixels 401 in the first row which are electrically continuous with the inverting input terminal of the operational amplifier 162 flows through the pixel bias line 407 via the pixel-select switch devices 403 and amplifying switching device 404. Signal charges are accumulated in the storage capacitor 164 by adding to the KTC noise of the reset switch 163.

On the other hand, regarding those pixels 401 in the first row which are not electrically continuous with the inverting input terminal of the operational amplifier 162 because MUX CLK2 is logic low, the signal current flows through the reference potential line 202, with which the pixels 401 are electrically continuous.

VgEVEN1 goes logic low, and then Signal SH goes logic high. Based on the electric charges accumulated in the storage capacitor 164, the signal sampling capacitor 165 is charged according to KTC noise as well as the signal current from the pixels 401.

After Signal SH goes logic low, during a logic high period of MUX, digital signals are obtained one after another according to differences among quantities of electric charge accumulated in the signal sampling capacitors 165 and noise sampling capacitors 166. Consequently, signals are acquired from the pixels 101 connected to one drive line 104a.

Also, AMP RESET goes logic high, and one of the electrodes of the conversion device 102 is clamped at (reset to) the potential of the reset bias line 405 via the reset switch device 402.

Next, MUX CLK1 goes logic low and MUX CLK2 goes logic high, and the operation described above is repeated. As a feature of the present embodiment, those pixels 401 in the first row which are electrically continuous with the inverting input terminal of the operational amplifier 162 are structured to allow nondestructive reads when MUX CLK2 is logic high. For that, signal charges are held, and although AMP RESET goes logic high at the same time, only the KTC noise generated when the switches 132a and 132b were closed the last time disappears and the signal charges are held as information in the pixels 401.

The operation described above allows the signal charges accumulated in the pixels 401 of the first row to be read out and converted into digital data. The above operation is repeated to convert the signal charges of the pixels 401 in the second to nth rows into digital data in sequence.

Through the series of actions, the KTC noise generated by the switches 132a and 132b in the multiplexer unit 131 is erased by turning on the reset switch 163 of the operational amplifier 162. In so doing, to avoid erasing signal charges at the same time, the switching devices 402 of the pixels 401 connected to non-conducting switches 132a or 132b are kept on, but since the pixels 401 are structured to allow nondestructive reads, signal information is not lost. Also, the KTC noise generated by the reset switch 163 and switching devices 402 can be cancelled out by correlated double sampling.

Also, even when the KTC noise is not cancelled out, since the signal charges obtained by the conversion devices 102 in the pixels 401 can be amplified into a current, the influence of noise charge quantity due to the KTC noise generated by the reset switch 163 or switching devices 402 can be reduced.

The present embodiment can almost halve the number of connection terminals 119 and connection terminals 203 using the multiplexer unit 131 and demultiplexer unit 200. Also, the noise charge of KTC noise in signal charges can be erased selectively. Alternatively, the KTC noise can be reduced sufficiently with respect to signal charges. Besides, the above description is also applicable to other embodiments of the present invention as appropriate.

### Fourth Embodiment

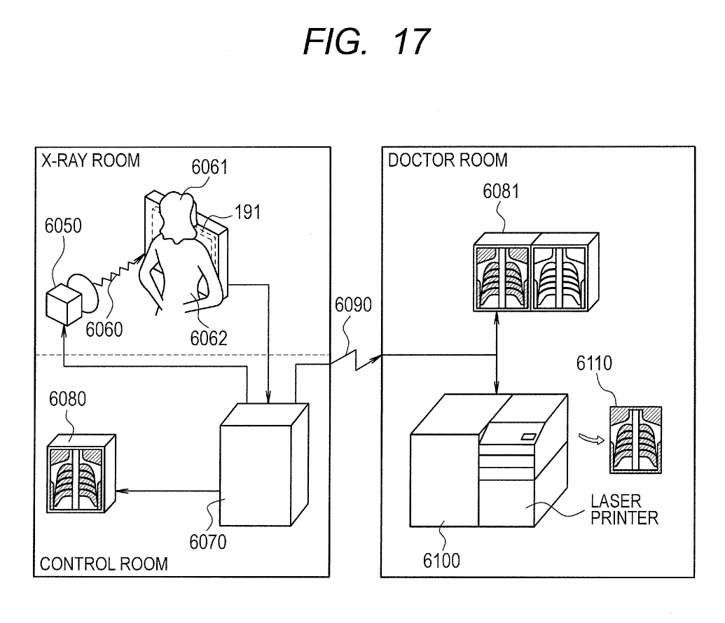

FIG. 17 is a diagram showing a configuration example of a radiation detection system according to a fourth embodiment of the present invention. The detection apparatus 191 according to any of the above embodiments is used for the radiation detection system. An x-ray beam 6060 generated by an x-ray tube 6050, which is a radiation source, penetrates the chest 6062 of a patient or subject 6061 and enters the detection apparatus 191 according to one of the above embodiments. The entering x-ray beam contains information about internal body parts of the patient 6061. In response to the entering x-ray beam, the scintillator 156 (FIG. 4) emits light, which is photoelectrically converted by a photoelectric conversion device to obtain electrical information. The information is converted into digital form and subjected to signal processing by an image processor 6070 serving as a signal processing unit, to allow the information to be observed on a display 6080 serving as a display unit of a control room. The image processor 6070 processes signals from the detection apparatus 191. The display 6080 displays signals from the image processor 6070.

Also, the information can be transferred to remote locations via a transmission processing unit such as a telephone line 6090 and displayed on a display 6081 serving as a display unit at another location such as a doctor room or saved in a recording unit such as an optical disk, allowing doctors at the remote locations to make a diagnosis. The information can also be recorded on a film 6110 serving as a recording medium using a film processor 6100 serving as a recording unit. The film processor 6100 stores the signals from the image processor 6070.

As described above, according to the first to fourth embodiments, during operation of the multiplexer unit 131, by closing the switches 132a or 132b used for the multiplexer unit 131, charges due to the KTC noise produced according to the capacitance of the data lines 105 can be erased selectively. This provides low-noise radiographic images. Also, some of the data lines 105 can be read preferentially without operating some of the switches 132a or 132b, and the resulting signal charges can be read nondestructively.

It should be noted that the embodiments described above merely illustrate concrete examples of carrying out the invention and are not to be interpreted as limiting the true scope of the present invention. That is, the present invention can be implemented in various forms without departing from the technical idea or major features of the invention.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-138929, filed Jun. 20, 2012, which is hereby incorporated by reference herein in its entirety.

What is claimed is:

1. A detection apparatus comprising:
a substrate which includes a plurality of pixels arranged in a matrix and adapted to generate pixel signals, a plurality of drive lines arranged in a column direction and each connected in common to a plurality of pixels in a row direction, a plurality of data lines arranged in the row direction and each connected in common to a plurality of pixels in the column direction, connection terminals smaller in number than the data lines, and a multiplexer unit provided between the connection terminals and the data lines;
a read circuit provided with a reset switch for supplying a constant potential to the connection terminals and connected to the connection terminals;
a drive circuit adapted to control driving of the plurality of pixels; and
a control circuit adapted to supply a control signal to the substrate and the read circuit,
wherein each of the plurality of pixels is provided with a conversion device for converting radiation or light into an electric charge and a switching device for transferring an electric signal based on the electric charge to the data line and adapted to generate a pixel signal based on the electric signal,
the drive lines include a first drive line connected to control electrodes of the switching devices of some of the pixels in one row and a second drive line connected to control electrodes of the switching devices of others of the pixels in the one row,
the data lines include a first data line connected to main electrodes of the switching devices of the pixels in one column and a second data line connected to main electrodes of the switching devices of the pixels in another column,
the multiplexer unit includes a first switch adapted to connect the first data line to one of the connection terminals and a second switch adapted to connect the second data line to the one connection terminal, and
the control circuit carries out a first step of turning on the first switch, and turning on and then turning off the reset switch, a second step of turning on and then turning off the switching devices of the pixels connected to the first drive line by the drive circuit, and then turning off the first switch, a third step of turning on the second switch, turning on and then turning off the reset switch, and then turning on and then turning off the switching devices of the pixels connected to the second drive line by the drive circuit, and a fourth step of turning off the second switch, the first step, the second step, the third step, and the fourth step being carried out in this order.

2. The detection apparatus according to claim 1, wherein:
the read circuit further includes a first sampling capacitor adapted to accumulate charge, a second sampling capacitor adapted to accumulate charge, a first sample-and-hold switch adapted to sample and hold the charge read out of the connection terminals in the first sampling capacitor, and a second sample-and-hold switch adapted to sample and hold the charge read out of the connection terminals in the second sampling capacitor; and
the control circuit carries out a first step of turning on the first switch, turning on and then turning off the reset switch, and turning on and then turning off the second sample-and-hold switch, a second step of turning on and then turning off the switching devices of the pixels connected to the first drive line by the drive circuit, turning on and then turning off the first sample-and-hold switch, and then turning off the first switch, a third step of turning on the second switch, turning on and then turning off the reset switch, turning on and then turning off the second sample-and-hold switch, turning on and then turning off the switching devices of the pixels connected to the second drive line by the drive circuit, and turning on and then turning off the first sample-and-hold switch, and the fourth step of turning off the second switch, the first step, the second step, the third step, and the fourth step being carried out in this order.

3. The detection apparatus according to claim 1, wherein:
the read circuit further includes an operational amplifier whose inverting input terminal is connected to the connection terminals and whose non-inverting input terminal is connected to a reference power supply, and a capacitor connected between an output terminal and the inverting input terminal of the operational amplifier; and
the reset switch is connected between the output terminal and inverting input terminal of the operational amplifier.

4. The detection apparatus according to claim 1, further comprising a demultiplexer unit connected to the drive lines.

5. The detection apparatus according to claim 4, wherein the demultiplexer unit includes a plurality of demultiplexers connected in series.

6. The detection apparatus according to claim 4, wherein the demultiplexer unit is provided on each of opposite ends of the drive lines.

7. The detection apparatus according to claim 6, wherein a plurality of the drive circuits are connected to the plurality of demultiplexer units, respectively.

8. The detection apparatus according to claim 1, wherein the conversion device includes a scintillator adapted to convert radiation into light and a photoelectric conversion device adapted to convert the light into an electric charge.

9. A detection system comprising:
the detection apparatus according to claim 1;
a signal processing unit adapted to process a signal from the detection apparatus;
a recording unit adapted to record a signal from the signal processing unit; and
a display unit adapted to display the signal from the signal processing unit.

10. A drive method for a detection apparatus which comprises a substrate, the substrate including a plurality of pixels arranged in a matrix and adapted to generate pixel signals, a plurality of drive lines arranged in a column direction and each connected in common to a plurality of pixels in a row direction, a plurality of data lines arranged in the row direction and each connected in common to a plurality of pixels in the column direction, connection terminals smaller in number than the data lines, and a multiplexer unit provided between the connection terminals and the data lines; a read circuit provided with a reset switch for supplying a constant potential to the connection terminals and connected to the connection terminals; and a drive circuit adapted to control driving of the plurality of pixels, wherein each of the plurality of pixels is provided with a conversion device for converting radiation or light into an electric charge and a switching device for transferring an electric signal based on the electric charge to the data line and adapted to generate a pixel signal based on the electric signal; the drive lines include a first drive line connected to control electrodes of the switching devices of some of the pixels in one row and a second drive line connected to control electrodes of the switching devices of others of the pixels in the one row; the data lines include a first data line connected to main electrodes of the switching devices of the pixels in one column and a second data line connected to main electrodes of the switching devices of the pixels in another column; the multiplexer unit includes a first switch adapted to connect the first data line to one of the connection terminals and a second switch adapted to connect the second data line to the one connection terminal; and a drive circuit of the detection apparatus carries out:
a first step of turning on the first switch, and turning on and then turning off the reset switch;
a second step of turning on and then turning off the switching devices of the pixels connected to the first drive line by the drive circuit, and then turning off the first switch, the second step being carried out after the first step;
a third step of turning on the second switch, turning on and then turning off the reset switch, and then turning on and then turning off the switching devices of the pixels connected to the second drive line by the drive circuit, the third step being carried out after the second step; and
a fourth step of turning off the second switch, the fourth step being carried out after the third step.
